(19) United States
(12) Patent Application Publication
(10) Pub. No.: US 2012/0206150 A1
(43) Pub. Date: Aug. 16, 2012

(54) ADJUSTABLE GAIN AMPLIFIER, AUTOMATED TEST EQUIPMENT AND METHOD FOR ADJUSTING A GAIN OF AN AMPLIFIER

(76) Inventor: Kyle David Holzer, Bountiful, UT (US)

(21) Appl. No.: 13/392,492

(22) PCT Filed: Aug. 27, 2009
(86) PCT No.: PCT/EP2009/006227

§ 371 Date: May 2, 2012

(51) Int. Cl. G01R 31/02; H03G 3/30

(52) U.S. Cl. 324/537; 330/278

(57) ABSTRACT

The adjustable gain amplifier comprises an amplifier transistor comprising a control terminal and a controllable path. The adjustable gain amplifier also comprises a variable impedance circuit, which is configured to provide variable impedance for varying a gain of the amplifier transistor. The load path of the amplifier transistor and the variable impedance circuit are coupled in series between a first supply potential feed and a second supply potential feed. The adjustable gain amplifier also comprises an active feedback circuit configured to stabilize a load path bias voltage of the amplifier transistor.

### CROSS-REFERENCES TO RELATED APPLICATIONS

This application is a Continuation of and claims priority to International Application No. PCT/EP2009/006227, filed on Aug. 27, 2009, titled “ADJUSTABLE GAIN AMPLIFIER, AUTOMATED TEST EQUIPMENT AND METHOD FOR ADJUSTING A GAIN OF AN AMPLIFIER,” by Holzer, et al, which is herein incorporated by reference.

### TECHNICAL FIELD

The present disclosure relates generally to the field of adjustable gain amplifiers and more specifically to the field of amplifier gain adjustment with automated test equipment.

### BACKGROUND

In many cases, it is desirable to provide signals having a large dynamic range. In some cases, an original signal may comprise a predetermined amplitude. It is often desirable to obtain an output signal derived from the original signal, such that the amplitude of the output signal may be adjusted. A signal path with adjustable gain or amplification may be used for this purpose.

In the following, some exemplary signal paths in automated test equipment will be described. Automated test equipment (ATE) test parameters typically require a large instantaneous dynamic range for both the source and the receiver. FIG. 1A illustrates a block schematic diagram of a first conventional signal path. The signal path 100 shown in FIG. 1A comprises a power amplifier 110 and a step attenuator 112. The step attenuator 112 is arranged after the power amplifier 110, as illustrated in FIG. 1A. For example, the integrated step attenuator 112 may be placed after a last power amplifier 110 to suppress a signal noise floor. The integrated step attenuator 112 can introduce distortion and may become a limiter for a stimulus maximum power.

FIG. 1B illustrates an exemplary block schematic diagram of another signal path. The signal path of FIG. 1B comprises a power amplifier 120 and a fixed attenuator 122. The fixed attenuator 122 is arranged after the power amplifier 120. In one exemplary embodiment, the fixed attenuator 122 may be placed after a last power amplifier 120 to suppress a signal noise floor. A stimulus maximum power is degraded by a value of the attenuator 122.

FIG. 1C illustrates an exemplary block schematic diagram of a third signal path. The signal path of FIG. 1C comprises an amplifier 130 and a digital-to-analog converter 132. In the signal path illustrated in FIG. 1C, it is possible to vary an amplifier gain by directly adjusting a gate voltage (or a gate-source-voltage VGS). For example, the gate voltage (or gate-source-voltage VGS) may be adjusted through a digital-to-analog converter (DAC), which may be an external digital-to-analog converter. In one exemplary embodiment, a DAC control adjusts VGS. However, the amplifier (or the amplifier transistor thereof) easily moves into a “diode region” (for example, in the output characteristic of the amplifier transistor), and distortion may be introduced. In addition, a settling time may be typically poor in the signal path illustrated in FIG. 1C.

### SUMMARY OF THE INVENTION

Embodiments of the present invention provide a solution to the challenges inherent in adjusting a gain amplifier with automated test equipment. In one exemplary embodiment an automated test equipment radio frequency field effect transistor (ATE RF FET) amplifier comprises adjustable gain feedback.

In one exemplary embodiment an adjustable gain amplifier is provided. The adjustable gain amplifier comprises an amplifier transistor comprising a control terminal and a controllable load path. The adjustable gain amplifier also comprises a variable impedance circuit, which is configured to provide a variable impedance for varying a gain of the amplifier transistor. The load path of the amplifier transistor and the variable impedance circuit are coupled in series between a first supply potential feed and a second supply potential feed. The adjustable gain amplifier also comprises an active feedback circuit configured to stabilize a load path bias voltage of the amplifier transistor. In this embodiment a variation of the impedance of the variable impedance circuit may allow for a substantial change of a load path bias current, while also keeping a load path bias voltage substantially stable. A stabilization of the load path bias voltage is obtained by the active feedback circuit, such that a high precision of the stabilization can be achieved and such that a transition to a highly non-linear region of operation of the amplifier transistor is avoided. Accordingly, the gain of the adjustable gain amplifier may be varied by variably adjusting a load path bias current, while keeping a variation of a load path bias voltage small.

In one exemplary embodiment, automated test equipment comprises a signal generator configured to provide a generator signal. The automated test equipment also comprises a device-under-test port for coupling a device-under-test signal from a device-under-test to an adjustable gain amplifier. The adjustable gain amplifier comprises an amplifier transistor comprising a control terminal and a controllable load path. The adjustable gain amplifier also comprises a variable impedance circuit, which is configured to provide variable impedance for varying a gain of the amplifier transistor. The controllable load path of the amplifier transistor and the variable impedance circuit are coupled in series between a first supply potential feed and a second supply potential feed. The adjustable gain amplifier also comprises an active feedback circuit configured to stabilize a load path bias voltage of the amplifier transistor. The adjustable gain amplifier is coupled between the signal generator and the device-under-test port to variably amplify the generator signal depending upon the gain adjustment and to obtain the device-under-test signal on the basis of the generator signal.

In one exemplary embodiment, automated test equipment comprises a device-under-test port for receiving a device-under-test signal from a device-under-test. The automated test equipment also comprises a signal analyzer for analyzing an analysis signal and an adjustable gain amplifier. The adjustable gain amplifier comprises an amplifier transistor comprising a control terminal and a controllable load path. The adjustable gain amplifier also comprises a variable impedance circuit, which is configured to provide variable impedance for varying a gain of the amplifier transistor. The load path of the amplifier transistor and the variable impedance circuit are coupled in series between a first supply potential feed and a second supply potential feed. The adjustable gain amplifier also comprises an active feedback circuit configured to stabilize a load path bias voltage of the amplifier transistor. The adjustable gain amplifier is coupled between the device-under-test port and the signal analyzer to variably amplify a device-under-test signal received by the device-under-test port and to provide the analysis signal on the basis of the device-under-test signal.

### BRIEF DESCRIPTION OF THE DRAWINGS

Embodiments of the present invention will be better understood from a reading of the following detailed description, taken in conjunction with the accompanying drawing figures in which like reference characters designate like elements and in which:

FIG. 1A, FIG. 1B, and FIG. 1C illustrate exemplary block schematic diagrams of power amplifier output paths;

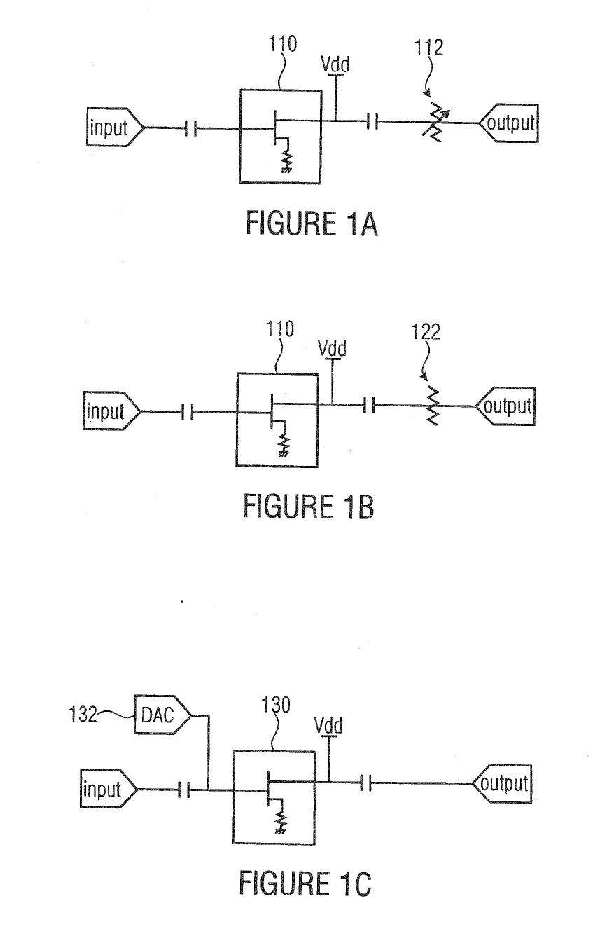

FIG. 2 illustrates an exemplary block schematic diagram of an adjustable gain amplifier in accordance with an embodiment of the present invention;

FIG. 3 illustrates an exemplary block schematic diagram of an adjustable gain amplifier in accordance with an embodiment of the present invention;

FIG. 4 illustrates an exemplary set of output characteristic curves of a field effect transistor amplifier in accordance with an embodiment of the present invention;

FIG. 5 illustrates an exemplary graphical representation of different bias points of a field-effect transistor amplifier in a set of output characteristic curves of the intersect transistor amplifier in accordance with an embodiment of the present invention;

FIG. 6A-6B illustrate exemplary block diagrams of automated test equipment in accordance with embodiments of the present invention; and

FIG. 7 illustrates an exemplary flow diagram of a method for adjusting a gain of an amplifier in accordance with embodiments of the present invention.

### DETAILED DESCRIPTION

Reference will now be made in detail to the preferred embodiments of the present invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail so as not to unnecessarily obscure aspects of the embodiments of the present invention. The drawings showing embodiments of the invention are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part. Generally, the invention can be operated in any orientation.

### Notation and Nomenclature:

Some portions of the detailed descriptions, which follow, are presented in terms of procedures, steps, logic blocks, processing, and other symbolic representations of operations on data bits within a computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “processing” or “accessing” or “executing” or “storing” or “rendering” or the like, refer to the action and processes of a computer system, or similar electronic computing device, that manipulates and transforms data represented as physical (electronic) quantities within the computer system's registers and memories and other computer readable media into other data similarly represented as physical quantities within the computer system memories or registers or other such information storage, transmission or display devices. When a component appears in several embodiments, the use of the same reference numeral signifies that the component is the same component as illustrated in the original embodiment.

Embodiments of the present invention provide solutions to the increasing challenges inherent in adjusting a gain amplifier with automated test equipment. In one exemplary embodiment, an automated test equipment radio frequency field effect transistor (ATE RF FET) amplifier comprises adjustable gain feedback.

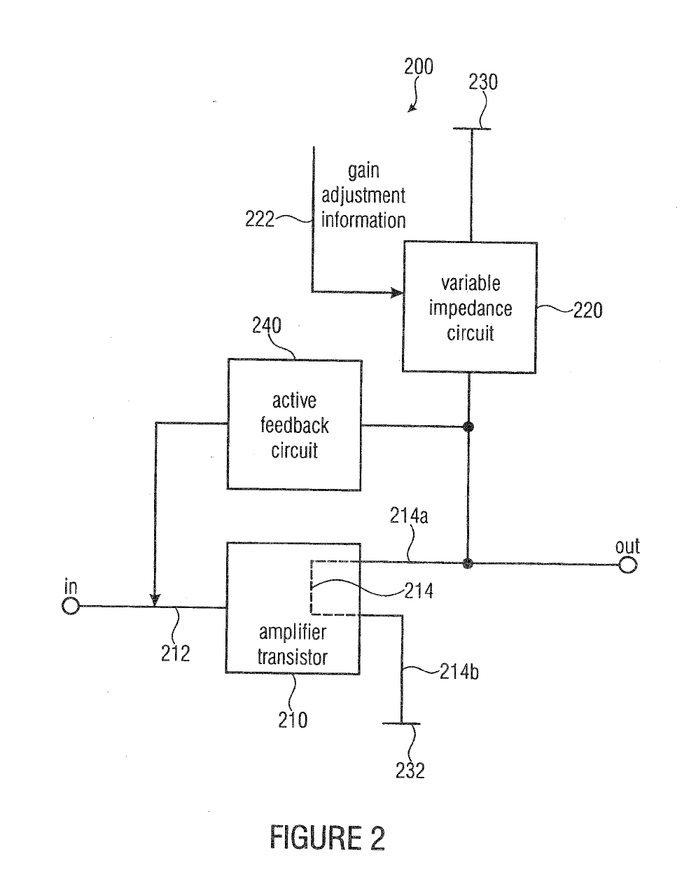

FIG. 2 illustrates an exemplary block schematic diagram of an adjustable gain amplifier 200 according to an embodiment of the present invention. The adjustable gain amplifier 200 comprises an amplifier transistor 210. The amplifier transistor 210 comprises a control terminal 212 and a controllable load path 214, which may, for example, have a first load path terminal 214a and a second load path terminal 214b. In addition, the variable gain amplifier comprises a variable impedance circuit 220, which is configured to provide a variable impedance that is dependent upon gain adjustment information 222. The adjustable gain amplifier 200 further comprises a first supply potential feed 230 and a second supply potential feed 232. As illustrated in FIG. 2, the load path 214 of the amplifier transistor 210 and the variable impedance circuit 220 are circuited in series between the first supply potential feed 230 and the second supply potential feed 232.

In addition, the adjustable gain amplifier 200 also comprises an active feedback circuit 240, which is configured to stabilize a load path bias voltage (e.g. a voltage across the load path 214 of the amplifier transistor 210), for example, by appropriately adjusting a bias at the control terminal 212 of the amplifier transistor 210.

Regarding the functionality of the adjustable gain amplifier 200, in one exemplary embodiment, the amplifier transistor 210 may be a field-effect transistor. In another exemplary embodiment, the amplifier transistor 210 may be a bipolar transistor.

In the case of a field-effect transistor, the control terminal 212 may be a gate terminal of the amplifier transistor 210 and the load path 214 may be a drain-source-path. Accordingly, the first load path terminal 214 may be a drain terminal and the second load path terminal 214b may be a source terminal. In contrast, if the amplifier transistor 210 is a bipolar transistor, the control terminal 212 may be a base terminal. The controllable load path 214 may be a collector-emitter path in this case, wherein the first controllable path terminal 214a is a collector terminal and the second controllable path terminal 214b is an emitter terminal.

In addition, the supply potential feeds 230, 232 may be configured to provide a supply voltage to the adjustable gain amplifier 200, such that in operation, there is a supply voltage (=potential difference) between the first supply potential feed 230 and the second supply potential feed 232, which supply voltage is typically a regulated dc voltage. Thus, the controllable load path 214 of the amplifier transistor 210 is biased via the variable impedance circuit 220, wherein the variable impedance circuit 220 is typically configured to pass direct current.

Accordingly, a variation of the impedance of the variable impedance circuit 220, which impedance is effective between the first supply potential feed 230 and the first controllable load path terminal 214a results in a change of a bias point of the controllable load path 214 of the amplifier transistor 210. This change of the bias point of the controllable load path 214 results in a change of a small-signal trans-conductance of the amplifier transistor 210 and thus in a change of the gain of the adjustable gain amplifier 200. However, a variation of the impedance of the variable impedance circuit 220 may change both the bias voltage across the controllable load path 214 and the bias current flowing through the controllable load path 214 in the absence of any counter-measures. In addition, a variation of the impedance of the variable impedance circuit 220, which is sufficient to vary the gain of the amplifier 200 over a desirable dynamic range, may have the effect that the voltage across the controllable load path reaches a small value. Accordingly, signal distortions may occur, because the amplifier transistor 210 would reach the so-called “diode region.”

In accordance with the present invention, the introduction of the active feedback circuit 240, which stabilizes the bias voltage across the controllable load path 214 (also designated as “load path bias voltage”) efficiently reduces or even suppresses the occurrence of signal distortions when varying the impedance of the variable- impedance circuit 220. Accordingly, the presence of the active feedback circuit 240, which stabilizes the load path bias voltage allows for a variation of the gain of the amplifier 200 over a large dynamic range by means of varying the impedance of the variable impedance circuit 220 while avoiding the occurrence of significant distortions.

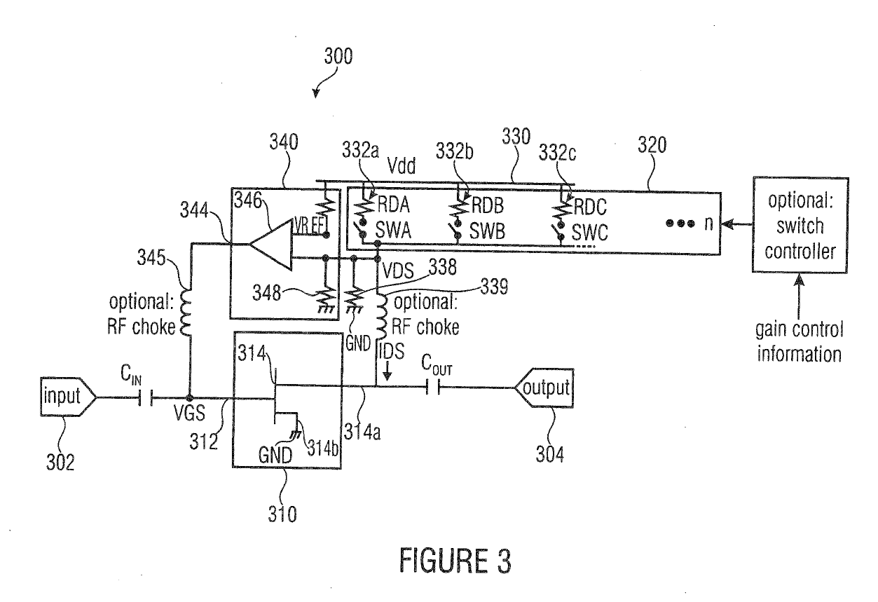

An exemplary block schematic diagram of an adjustable gain amplifier according to another embodiment of the invention is illustrated in FIG. 3. The adjustable gain amplifier illustrated in FIG. 3 is designated in its entirety with 300. The adjustable gain amplifier 300 comprises an amplifier input 302 (“input”) and an amplifier output 304 (“output”). The adjustable gain amplifier 300 comprises an amplifier transistor 310, which is, for example, an n-channel junction field-effect transistor. A gate terminal 312 of the amplifier transistor 310 is coupled to the input terminal 302 of the amplifier 300 via an input capacitance C_{IN}, which acts as a de-block. A drain terminal 314a of the amplifier transistor 310, which may be considered as a first controllable load path terminal, is coupled to the amplifier output 304 via an output capacitance C_{OUT}. In addition, a source terminal 314b of the amplifier transistor 310, which may be considered as a second controllable load path terminal, is coupled to a reference potential GND, which may be considered as a second supply potential.

Further, the adjustable gain amplifier 300 comprises a variable impedance circuit 320, which is circuited between a first supply potential feed 330 and the drain terminal 314a of the amplifier transistor 310. In addition, the drain terminal 314a of the amplifier transistor 310 may be coupled with the reference potential GND via an optional shunt resistor 338. Preferably an RF choke inductor 339 is used at the drain output of the transistor amplifier regardless of the variable impedance element. For example the RF choke inductor may be circuited between the drain terminal 314a of the amplifier transistor 314 and the variable impedance circuit 320. The variable gain amplifier 300 also comprises an active feedback circuit 340, the input of which is coupled to the drain terminal 314a of the amplifier transistor 310 (or to a node between the drain terminal 314a of the amplifier transistor 310 and the variable impedance circuit 320). An output 344 of the active feedback circuit 340 is coupled to the gate terminal 312 of the amplifier transistor 310 to provide a gate bias voltage VGS to the gate terminal 312. Preferably, an RF choke inductor 345 is included at the amplifier transistor gate input, for example circuited between the output 344 of the active feedback circuit 340 and the gate terminal 312 of the amplifier transistor 310.

In the following, details of the variable impedance circuit 320 and of the active feedback circuit 340 will be described. The variable impedance circuit 320 comprises a plurality of switchable resistor paths 332a, 332b, 332c. Each of the switchable resistor paths 332a, 332b, 332c comprises a series circuit of a resistor and a corresponding switch. For example, the switchable resistor path 332a comprises a series circuit of a resistor RDA and a switch SWA. Similarly, the second switchable resistor path comprises a series circuit of a resistor RDB and a switch SWB. The third switchable resistor path 332c comprises a series circuit of a resistor RDC and a switch SWC. Accordingly, by opening and closing the switches SWA, SWB, SWC, a single one of the resistors RDA, RDB, RDC can be selected. Alternatively, by closing a plurality of the switches SWA, SWB, SWC at the same time, it is possible to activate a plurality of switchable resistor paths at the same time, thereby creating a parallel circuit of a plurality of resistors RDA, RDB, RDC. Thus, if the variable impedance circuit 320 comprises N parallel switchable resistor paths 332a, 332b, 323c . . . , which all comprise resistors of different values, it is possible to obtain a total of 2^{N}−1 different finite resistor settings (and, in addition, a switch-off-state of the variable impedance circuit). Assuming now that different effective resistances of the switchable impedance circuit 320 correspond to different gain values of the variable gain amplifier 300, it can be seen that a total of 2^{N}−1 different gain settings (and, in addition, a turn-off state of the amplifier transistor 310) can be obtained by using the 2^{N} different switching combinations of the switches SWA, SWB, SWC of the switchable resistor paths 332a, 332b, 332c of the variable impedance circuit 320.

The active feedback circuit 340 comprises a difference amplifier 346, for example, an operational amplifier, and, typically, comprises a high input impedance, higher than the impedance presented by the variable impedance circuit. In addition, the active feedback circuit 340 comprises a reference value provider, which is configured to provide a feedback reference value for the difference amplifier 346. The reference value provider may, for example, take the form of a voltage divider comprising resistors 348a, 348b. The voltage divider may, for example, be coupled between the reference potential GND and a supply potential Vdd, which is present at the first supply potential feed 330, to provide a feedback reference voltage VREF to the first input of the difference amplifier 346. Thus, the feedback reference potential VREF lies between the first supply potential Vdd and the reference potential GND. The second input of the difference amplifier 346 is coupled to the drain terminal 314a of the amplifier transistor 310, such that the drain potential VDS is present at the second input of the difference amplifier 346.

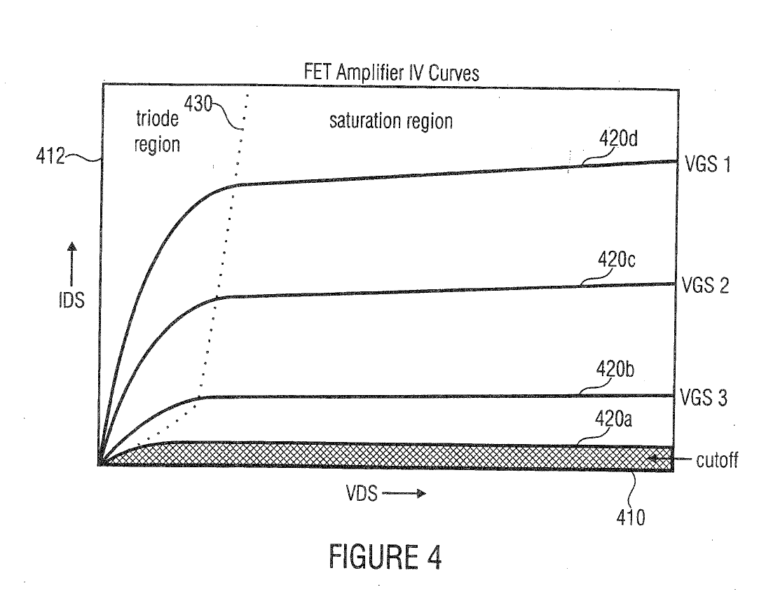

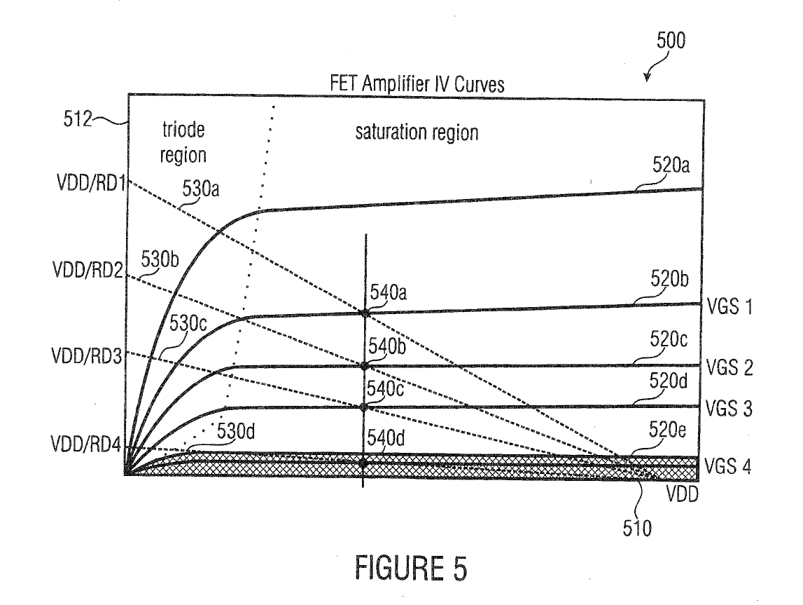

The difference amplifier 346 may be configured to adjust, alone or in combination with additional regulation circuitry, the gate potential VGS, which is applied to the gate terminal 312 of the amplifier transistor 310, such that the drain potential at the drain terminal 314a of the amplifier transistor 310 is regulated to take (or approximate) the reference potential VREF. Accordingly, the active feedback circuit 340 is configured to regulate the drain potential towards the feedback reference potential VREF independent from an impedance setting of the variable impedance circuit 320. For example, the active feedback circuit 340 may be designed such that the drain potential (or drain-source-voltage) VDS of the amplifier transistor 310 varies by no more than one volt for the different settings of the variable impedance circuit 320 (with the exception of an off-state of the variable impedance circuit 320). In some embodiments, the active feedback circuit 340 may also be configured to regulate the drain potential (or drain source voltage) of the amplifier transistor 310 such that the drain source voltage varies by no more than 20%, or even by no more than 10%, over the different settings of the variable impedance circuit 320 (with the exception of the off-state). In the following, the operation of the present circuit will be briefly discussed taking reference to FIGS. 4 and 5.

FIG. 4 shows a graphical representation of an output characteristic of the FET amplifier. An abscissa 410 describes the drain-source-voltage VDS of the amplifier transistor 310, and an ordinate 412 describes a drain current VDS of the transistor 310. A set of so-called “Adjustable Gain Feedback IV Curves” 420a, 420b, 420c, 420d for the RF FET amplifier describe the behavior of the load path of the transistor 310 for different gate source voltages, for example VGS1, VGS2, VGS3. As can be seen, there are gate-source voltages, for which the drain current IDS is very small. A region of the output characteristic in which the gate-source voltage VGS is too small to turn on the transistor is designated as “cut-off.” Moreover, it should be noted that the output characteristic of the transistor 310 comprises a saturation region in which the drain current IDS is only weakly dependent on the drain-source voltage VDS for a given gate-source voltage and wherein this dependency is approximately linear. In contrast, there is a so-called “triode region” in which the drain current comprises a strong and non-linear dependency on the drain source voltage for a given gate source voltage. A boundary between the triode region and the saturation region can be approximated by a parabola 430 in the output characteristic.

Taking reference now to FIG. 5, the operation of the amplifier circuit 300 will be discussed in detail. FIG. 5 illustrates another graphical representation of an output characteristic of the amplifier transistor 310. An abscissa 510 describes a drain-source-voltage VDS of the amplifier transistor 310, an ordinate 512 describes a drain current IDS of the field-effect transistor 310. A set of curves 520a, 520b, 520c, 520d, 520e describes a relationship between the drain-source-voltage VDS and the drain current IDS for different gate source voltages VGS1, VGS2, VGS3, VGS4 of the field-effect transistor 310. In addition, load lines 530a, 530b, 530c, 530d represent the current IDS provided by the variable impedance circuit 320 that are dependent upon the supply voltage Vdd (referenced to the reference potential GND) and the resistance presented by the variable impedance circuit 320. As can be seen, the “slope” of the load lines varies depending upon the impedance presented by the variable impedance circuit 320.

As can be seen from the graphical representation 500 of FIG. 5, a load path operating point is determined by an intersection of a current load line (which is determined by the supply voltage Vdd and the impedance presented by the variable impedance circuit, for example, RD1, RD2, RD3, RD4, or RDA, ROB, RDE, or any combination thereof) and the current one of the field-effect transistor load path characteristic lines 520a, 520b, 520c, 520d, 520e associated with the currently-applied gate-source- voltage VGS.

According to the present invention, the active feedback circuit 340 is configured to stabilize the drain-source-voltage of the field-effect transistor 310. Accordingly, it can be ensured, by means of the active feedback circuit 340, that a variation of the drain source voltage of the field-effect transistor 310 remains below a predetermined limit for change of the impedance of the variable impedance circuit 320.

In one exemplary embodiment, the applied voltage Vdd, which is present between the first supply potential feed 330 and the second supply potential feed or reference potential feed GND is a regulated voltage, which remains at least approximately constant (for example, within a limit of +/−5% or +/−10%) during the operation of the amplifier. Further, in one exemplary embodiment, the variable impedance circuit 320 is configured to provide a plurality of, for example, four different impedance values RD1, RD2, RD3, RD4 between the first potential feed 330 and the drain terminal 314a of the transistor 310, for example, RD1<RD2<RD3<RD4. Accordingly, a drain-source bias point 540a is obtained if the variable impedance circuit 320 presents the impedance RD1 and the active feedback circuit 340 adjusts or regulates the gate source voltage of the field-effect transistor 310 to a value VGS 1. If the impedance presented by the variable impedance circuit 320 is changed to a value RD2, an output bias point 540b of the field-effect transistor 310 will be reached, wherein the active feedback circuit 240 regulates the gate-source-voltage VGS of the field-effect transistor 310 to the value VGS2. Similarly, load path operation points 540c, 540d will be reached for impedance values of RD3 and RD4, respectively, wherein gate-source voltages VGS3, VGS4 will be adjusted by the active feedback circuit 340.

To summarize the above, the operation of the adjustable gain amplifier 300 has been described taking reference to the adjustable gain feedback IV curves for the RF FET amplifier illustrated in the graphical representation 500. As can be seen in FIG. 5, the feedback (which is typically provided by the active feedback circuit 340) holds the drain-source-voltage VDS constant (or at least approximately constant). Accordingly, a small signal distortion is minimized by keeping the FET amplifier in the saturation region of operation through the active feedback method.

The gain of the amplifier is adjusted by bringing the amplifier transistor to different load path bias points 540a, 540b, 540c, 540d, at which the transistor comprises different trans-conductance values. In addition, the impedance presented by the variable impedance circuit 320 may also comprise an impact on a small single gain for radio frequency (RF) signals unless there is a radio frequency decoupling (for example, a choke inductor circuited between the drain terminal 314a and the variable impedance circuit 320).

If the variable impedance element 220 is a resistor network (e.g. the resistor network 320, as shown in FIG. 3) there may be an impedance change even visible at DC. If the variable impedance element 220 is a variably biased FET the impedance variation will only be visible in the frequency response—especially in the higher GHz range frequency response depending on the length of the “stub.”

To further summarize the present invention, the invention creates an adjustable gain feedback for an ATE RF FET amplifier. The invention creates a method of adjusting an ATE RF FET amplifier gain by varying a RD resistance (e.g. a resistance of the variable impedance circuit 320) and through active feedback of a drain-source-voltage VDS to directly adjust a gate-source voltage VGS. In the inventive apparatus, the gate voltage (or gate-source-voltage) VGS is directly adjusted according to a voltage drop across a sense resistance RD (e.g. the resistance presented by the variable impedance circuit 320) in paths of drain current IDS. The sense resistance value is varied by re-routing the drain current IDS through varying combinations of parallel resistors (e.g. RDA, RDB, RDC). Additionally, this resistance variation may optionally be realized by an active variable attenuator such as a series field-effect transistor (FET) operating in the triode region. In other words, in some embodiments, the variable impedance circuit 320 may be replaced by a field-effect transistor, which is operated to act as a variable resistor.

Embodiments according to the invention may avoid a degradation of the field-effect transistor amplifier high-power performance with addition of an attenuator of the amplifier. Other embodiments according to the invention may also minimize a small signal distortion by keeping the field-effect transistor amplifier in the saturation region of operation through the active feedback methods. Details can be seen in FIGS. 4 and 5. Embodiments according to the invention may also speed-up a settling response to steady-state gain of the FET amplifier through the active feedback method.

Furthermore, it should be noted that the number of possible gain settings (Gp) binarily increases with the number of RD resistor options (RDn): Gp_{—}=2^{RDn}.

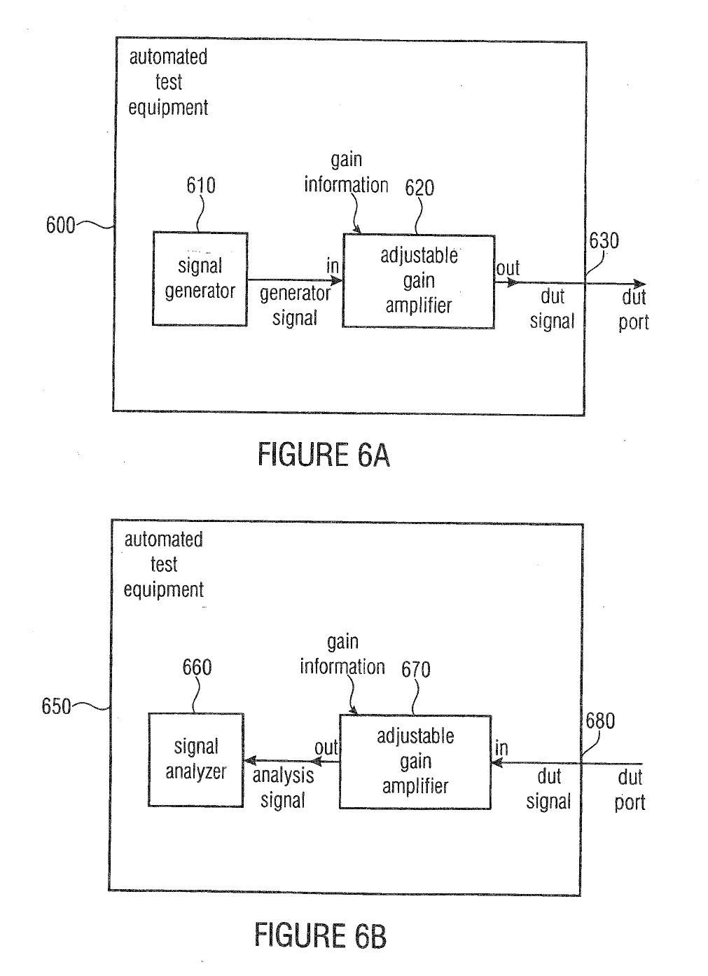

In the following, automated test equipment comprising the amplifier 200 according to FIG. 2 or the amplifier 300 according to FIG. 3 will be described. FIG. 6a illustrates a block schematic diagram of a first automated test equipment according to an embodiment of the invention. The automated test equipment 600 comprises a signal generator 610, which may, for example, be a radio frequency signal generator and which may be configured to provide radio frequency signals having a carrier frequency between 300 kHz and 300 GHz. The signal generator 610 may, for example, be configured to provide a modulated radio frequency signal having adjustable characteristics and/or the modulation content. The signal provided by the signal generator 610 is designated as a “generator signal”. The automated test equipment 612 comprises an adjustable gain amplifier 620, which receives, at its input (“IN” or “INPUT”), the generator signal from the signal generator 610. The adjustable gain amplifier 620 further provides, at its output (“OUT”, “OUTPUT”), a device-under-test signal, which is routed to a device-under-test port 630. Accordingly, the adjustable gain amplifier 620 is coupled into the signal path between the signal generator 610 and the device-under-test port 630 to extend the dynamic range of the device-under-test signal when compared to the generator signal provided by the signal generator 610. In particular, there may be a test controller configured to send gain information to the adjustable gain amplifier to adjust the impedance provided by the variable impedance circuit 220, 320.

FIG. 6b illustrates an exemplary block schematic diagram of automated test equipment 650 according to another embodiment of the invention. The automated test equipment 650 comprises a signal analyzer 660, which is configured to receive an analysis signal and to extract parameters from the analysis signal (for example, information about a frequency of the analysis signal, a spectrum of the analysis signal, a power of the analysis signal, and/or a modulation content of the analysis signal). Alternatively, the signal analyzer 660 may be configured to decide whether the analysis signal fulfills a predetermined requirement (for example, a predetermined power, a predetermined phase noise requirement, and so on). The automated test equipment 650 further comprises an adjustable gain amplifier 670, which may be identical to the adjustable gain amplifier 200 of FIG. 2 or the adjustable gain amplifier 300 of FIG. 3. The adjustable gain amplifier 670 may, for example, provide the analysis signal to the signal analyzer 660. The automated test equipment 650 further comprises a device-under-test port 680, which is configured to be coupled to a device-under-test, to receive a device-under-test signal from the device-under-test. The device-under-test port 680 may, for example, be coupled to an input of the adjustable gain amplifier 670. Accordingly, the adjustable gain amplifier 670 is coupled into the signal path between the device-under-test port 680 and the signal analyzer 660. By providing an adjustable amplification to the device-under-test signal, the adjustable gain amplifier 670 may serve to increase an effective usable dynamic range of the signal analyzer. For this purpose, the adjustable gain of the adjustable gain amplifier 670 may be adjusted by a test control circuitry in accordance with the test program. Alternatively, the signal analyzer 660 may provide gain adjustment information to the adjustable gain amplifier 670 if it is found that the analysis signal is too strong or weak.

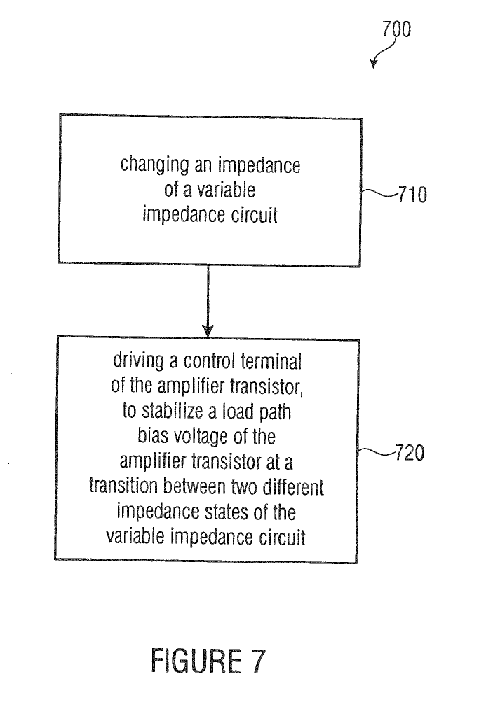

FIG. 7 shows a flow chart of an exemplary method for adjusting a gain of an amplifier comprising an amplifier transistor and a variable impedance circuit, wherein the load path of the amplifier transistor and the variable impedance circuit are coupled in series between a first supply potential feed and a second supply potential feed. The method comprises a step 710 of changing an impedance of the variable impedance circuit. The method 700 also comprises a step 720 of driving a control terminal of the amplifier transistor to stabilize a load path bias voltage of the amplifier transistor. The method 700 can be supplemented by any of the features and functionalities described herein, also with respect to the adjustable gain amplifier 200, 300.

To summarize the above, the present invention creates an adjustable gain feedback for an automated test equipment radio frequency amplifier. A gain can be adjusted with a moderate circuit effort without seriously compromising signal integrity. Further, a settling time during gain adjustment can be improved in some other embodiments by the usage of the active feedback.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. An adjustable gain amplifier comprising:
an amplifier transistor comprising a control terminal and a controllable load path;
a variable impedance circuit configured to provide a variable impedance for varying a gain of the amplifier transistor, wherein the controllable load path of the amplifier transistor and the variable impedance circuit are coupled in series between a first supply potential feed and a second supply potential feed; and
an active feedback circuit configured to stabilize a load path bias voltage of the amplifier transistor.

2. The adjustable gain amplifier according to claim 1, wherein the variable impedance circuit comprises a plurality of resistors coupled with the controllable load path of the amplifier transistor via corresponding switches, and wherein different combinations of one or more of the resistors are switchable in series with the controllable load path of the amplifier transistor between the first supply potential feed and the second supply potential feed.

3. The adjustable gain amplifier according to claim 2, wherein the plurality of resistors and corresponding switches of the variable impedance circuit comprise a plurality of switched resistor paths coupled in parallel, wherein each of the switched resistor paths comprises a series connection of a resistor and a switch, and wherein the variable impedance circuit further comprises a switch controller configured to activate different combinations of the switches dependent on a gain control to allow for an activation of different combinations of one or more of the resistors in series with the controllable load path of the transistor.

4. The adjustable gain amplifier according to claim 3, wherein the plurality of switched resistor paths of the variable impedance circuit comprises N switched resistor paths coupled in parallel, with N>2, wherein the different switched resistor paths comprise different on-resistances; and wherein the switch controller is configured to activate 2^{N}−1 different combinations of switches or 2^{N} different combinations of the switches depending on the gain control.

5. The adjustable gain amplifier according to claim 1, wherein the variable impedance circuit is configured as a direct current sense impedance for sensing a direct current bias current through the load path of the amplifier transistor and as an alternating current load impedance for adjusting an alternating current gain of the amplifier.

6. The adjustable gain amplifier according to claim 1, wherein the variable impedance circuit comprises a variable semiconductor resistance.

7. The adjustable gain amplifier according to claim 6, wherein the variable semiconductor resistance of the variable impedance circuit comprises an impedance variation field effect transistor, and wherein the variable impedance circuit is further configured to selectively bias the impedance variation field effect transistor to operate at different bias points in a triode region of its output characteristic.

8. The adjustable gain amplifier according to claim 1, wherein the active feedback circuit is further configured to adjust a bias at the control terminal of the amplifier transistor dependent on a voltage drop across the variable impedance circuit.

9. The adjustable gain amplifier according to claim 1, wherein the active feedback circuit is further configured to adjust a bias at the control terminal of the amplifier transistor to maintain the amplifier transistor in a saturation region independent from an impedance setting of the variable impedance circuit.

10. The adjustable gain amplifier according to claim 1, wherein the active feedback circuit is further configured to regulate a voltage across the load path of the amplifier transistor to a predetermined value.

11. The adjustable gain amplifier according to claim 10, wherein the active feedback circuit comprises a difference amplifier configured to adjust a bias at the control terminal of the amplifier transistor to regulate a voltage drop across the variable impedance circuit to a predetermined value, and wherein the variable impedance circuit is configured as a current sense impedance for sensing a current through the load path of the amplifier transistor.

12. A method for adjusting a gain of an amplifier, the method comprising:
changing an impedance of a variable impedance circuit, wherein the changing impedance of the variable impedance circuit varies a gain of an amplifier transistor; and
regulating a bias voltage at a control terminal of the amplifier transistor to stabilize a load path bias voltage of the amplifier transistor at a transition between two different impedance states of the variable impedance circuit, wherein the load path of the amplifier transistor and the variable impedance circuit are coupled in series between a first supply potential feed and a second supply potential feed.

13. The method of claim 12, wherein changing the impedance of the variable impedance circuit comprises switching one or more of a plurality of resistors in series with the load path of the amplifier transistor between the first supply potential feed and the second supply potential feed, and wherein different combinations of the plurality of resistors are switchable in series with the load path of the amplifier transistor via corresponding switches.

14. The method of claim 13, wherein the plurality of resistors and corresponding switches comprise a plurality of switched resistor paths coupled in parallel, wherein each of the switched resistor paths comprises a series connection of a resistor and a switch, and wherein switching one or more of the plurality of resistors in series with the load path of the amplifier transistor comprises activating different combinations of the switches dependent on a gain control to allow for an activation of different combinations of one or more of the resistors in series with the load path of the transistor.

15. The method of claim 14, wherein the plurality of switched resistor paths of the variable impedance circuit comprises N switched resistor paths coupled in parallel, with N>2, wherein the different switched resistor paths comprise different on-resistances; and wherein activating different combinations of switches comprises activating 2^{N}−1 different combinations of switches or 2^{N} different combinations of the switches depending on the gain control.

16. The method of claim 12 further comprising:
sensing a direct current bias current through the load path of the amplifier transistor; and
adjusting an alternating current gain of the amplifier transistor, wherein the variable impedance circuit is configured to sense the direct current bias current through the load path of the amplifier transistor.

17. The method of claim 12, wherein changing the impedance of the variable impedance circuit comprises varying a semiconductor resistance of the variable impedance circuit.

18. The method of claim 17, wherein the varying a semiconductor resistance of the variable impedance circuit comprises selectively biasing an impedance variation field effect transistor to operate at different bias points in a triode region of its output characteristic.

19. The method of claim 12 further comprising:
adjusting a bias at the control terminal of the amplifier transistor depending on a voltage drop across the variable impedance circuit.

20. The method of claim 12 further comprising:
adjusting a bias at the control terminal of the amplifier transistor to maintain the amplifier transistor in a saturation region independent from an impedance setting of the variable impedance circuit.

21. The method of claim 12 further comprising:
regulating a voltage across the load path of the amplifier transistor to a predetermined value; and
adjusting a bias at the control terminal of the amplifier transistor to regulate a voltage drop across the variable impedance circuit or a bias voltage of the load path to a predetermined value, and wherein the variable impedance circuit is configured as a current sense impedance for sensing a current through the load path of the amplifier transistor.

23. An automated test equipment comprising:
a signal generator configured to generate a signal;
a device-under-test port operable for coupling a device-under-test signal to a device-under-test; and
an adjustable gain amplifier comprising:
an amplifier transistor comprising a control terminal and a controllable load path;
a variable impedance circuit configured to provide a variable impedance dependent on a gain adjustment, wherein the controllable load path of the amplifier transistor and the variable impedance circuit are coupled in series between a first supply potential feed and a second supply potential feed; and
an active feedback circuit configured to stabilize a load path bias voltage of the amplifier transistor, wherein the adjustable gain amplifier is coupled between the signal generator and the device-under-test port to variably amplify the generator signal dependent on the gain adjustment, and to obtain the device-under-test signal on the basis of the generator signal.

24. An automated test equipment comprising:
a device-under-test port for receiving a device-under-test signal from a device-under-test;
a signal analyzer for analyzing an analysis signal; and
an adjustable gain amplifier comprising:
an amplifier transistor comprising a control terminal and a controllable load path;
a variable impedance circuit configured to provide a variable impedance dependent on a gain adjustment, wherein the controllable load path of the amplifier transistor and the variable impedance circuit are coupled in series between a first supply potential feed and a second supply potential feed; and
an active feedback circuit configured to stabilize a load path bias voltage of the amplifier transistor, wherein the adjustable gain amplifier is coupled between the device-under-test port and the signal analyzer to variably amplify a device-under-test signal received via the device-under-test port and to provide the analysis signal on the basis of the device-under-test signal.
